(19) United States
(12) Patent Application Publication
(10) Pub. No.: US 2009/0159119 A1
(43) Pub. Date: Jun. 25, 2009

(54) TECHNIQUE AND APPARATUS FOR MANUFACTURING FLEXIBLE AND MOISTURE RESISTIVE PHOTOVOLTAIC MODULES

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/372,720

(22) Filed: Feb. 17, 2009

Related U.S. Application Data
(63) Continuation-in-part of application No. 11/692,806, filed on Mar. 28, 2007.
(60) Provisional application No. 61/076,573, filed on Jun. 27, 2008.

(51) Int. Cl. H01L 31/048; B32B 37/00

(52) U.S. Cl. 136/251; 156/182

(57) ABSTRACT

An apparatus and method of making moisture resistant solar cells, strings and modules is provided. The method includes reducing the roughness of the finger patterns by coating them fully or partially with a surface preparation film. The surface preparation film firmly attaches itself to underlying finger patterns and electrical leads while forming a smooth surface on which a moisture barrier film is subsequently deposited. Process flows to obtain moisture resistive solar cells, solar cell strings are described.

### BACKGROUND OF THE INVENTION

This application is a continuation-in-part of U.S. patent application Ser. No. 11/692,806, filed Mar. 28, 2007, entitled “TECHNIQUE FOR MANUFACTURING PHOTOVOLTAIC MODULES,” and this application also relates to and claims priority from United States Provisional Application No. 61/076,573, filed Jun. 27, 2008, entitled “TECHNIQUE FOR MANUFACTURING FLEXIBLE AND MOISTURE RESISTIVE PHOTOVOLTAIC MODULES”, both of which are expressly incorporated herein by reference.

### FIELD OF THE INVENTION

The present invention relates to method and apparatus for manufacturing solar or photovoltaic modtiles for better environmental stability.

### DESCRIPTION OF THE RELATED ART

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Amorphous Si [a-Si], cadmium telluride [CdTe] and copper-indium-selenide (sulfide) [CIGS(S), or Cu(In,Ga)(S,Se)₂ or CuIn₍₁₋ₓ₎, Gaₓ (S_{y}Se_{(1-y)})ₖ, where 0≦x≦1, 0≦y≦1 and k is approximately 2], are the three important thin film solar cell materials. The structure of a conventional Group IBIIIAVIA compound photovoltaic cell such as a CIGS(S) thin film solar cell is shown in FIG. 1. The device 10 is fabricated on a substrate 11, such as a sheet of glass, a sheet of metal, an insulating foil or web, or a conductive foil or web. The absorber film 12, which comprises a material in the family of Cu(In,Ga,Al)(S,Se,Te)₂ , is grown over a conductive layer 13 or a contact layer. which is previously deposited on the substrate II and which acts as the electrical ohmic back contact to the device. The most commonly used contact layer or conductive layer 13 in the solar cell structure of FIG. 1 is molybdenum (Mo). If the substrate itself is a properly selected conductive material such as a Mo foil, it is possible not to use a conductive layer 13, since the substrate 11 may then be used as the ohmic contact to the device. The conductive layer 13 may also act as a diffusion barrier in case the metallic foil is reactive. For example, foils comprising materials such as Al, Ni, Cu may be used as substrates provided a barrier such as a Mo layer, a W layer, a Ru layer, a Ta layer etc., is deposited on them protecting them from Se or S vapors. The barrier is often deposited on both sides of the foil to protect it well. After the absorber film 12 is grown, a transparent layer 14 such as a CdS, transparent conductive oxide (TCO) such as ZnO or CdS/TCO stack is formed on the absorber film. Radiation, R, enters the device through the transparent layer 14. Metallic grids or finger patterns (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 11.

Solar cells have relatively low voltage of typically less than 2 volts. To build high voltage power supplies or generators, solar cells are interconnected to form circuits which are then laminated in a protective package forming modules. There are two ways to interconnect thin film solar cells to form circuits and then fabricate modules with higher voltage and/or current ratings. If the thin film device is formed on an insulating surface, monolithic integration is possible. In monolithic integration, all solar cells are fabricated on the same substrate and then integrated or interconnected on the same substrate by connecting negative terminal of one cell to the positive terminal of the adjacent cell (series connection). A monolithically integrated Cu(In,Ga,Al)(S,Se,Te)₂ compound thin film circuit structure 20 comprising series connected cell sections 18 is shown in FIG. 2A. In this case the contact layer is in the form of contact layer pads 13a separated by contact isolation regions or contact scribes 15. The compound thin film is also in the form of compound layer strips 12a separated by compound layer isolation regions or compound layer scribes 16. The transparent conductive layer, on the other hand, is divided into transparent layer islands 14a by transparent layer isolation regions or transparent layer scribes 17. As can be seen in FIG. 2A, the contact layer pad 13a of each cell section 18 is electrically connected to the transparent layer island 14a of the adjacent cell section. This way voltage generated by each cell section is added to provide a total voltage of V from the circuit structure 20.

The second way of integrating thin film solar cells into circuits is to first fabricate individual solar cells and then interconnect them through external wiring. This approach is not monolithic, i.e. all the cells are not on the same substrate. FIG. 2B schematically shows integration of three CIGS(S) solar cells 10 into a circuit 21 section, wherein the CIGS(S) cells 10 may be fabricated on conductive foil substrates with a structure similar to the one depicted in FIG. 1.

Irrespective of the integration approach used, after the solar cells are electrically interconnected into a circuit such as the circuit 21 shown in FIG. 2B, the circuit needs to be packaged to form an environmentally stable and physically well-protected product which is a module. FIG. 3 shows an exemplary form of a package after the integrated cells of FIG. 2B are encapsulated in a protective package. The structure in FIG. 3 is a flexible module structure that is very attractive in terms of its flexibility and light weight. Some of the commonly used layers in the structure of FIG. 3 are a top film 30, a flexible encapsulant 31, and a backing material 32. The top film 30 is a transparent durable layer such as TEFZEL® manufactured by DuPont. The most commonly used flexible encapsulant is slow cure or fast cure EVA (ethyl vinyl acetate). The backing material 32 may be a TEFZEL® film, a TEDLAR® film (produced by DuPont) or any other polymeric film with high strength. It should be noted that since the light enters from the top, the backing material 32 does not have to be transparent and therefore it may comprise inorganic materials such as metals.

Although desirable and attractive, the flexible thin film photovoltaic module of FIG. 3 may have the drawback of environmental instability. Specifically, the commercially available and widely used top films and flexible encapsulants are semi-permeable to moisture and oxygen therefore corrosion and cell deterioration may be observed after a few years of operation of the flexible module in the field. Therefore, there is a need to develop alternative packaging techniques for modules to provide resistance to moisture absorption and diffusion to the active regions of the circuit.

### SUMMARY OF THE INVENTION

The present invention, in one aspect, is directed to methods for manufacturing solar or photovoltaic modules for better environmental stability.

The present invention, in another aspect, is directed to environmentally stable solar or photovoltaic modules.

In a particular embodiment, there is described a method of manufacturing a photovoltaic module by providing at least two solar cells, each of the at least two solar cells having a top illuminated surface and two terminals. There then follows the steps of electrically interconnecting the at least two solar cells with a conductor between at least one of the terminals of each of the at least two solar cells to form a circuit, and coating at least an entire side of the circuit that corresponds to and includes the top illuminated surface of the at least two solar cells with a moisture barrier film to form a moisture-resistant surface on the circuit.

In another embodiment a method of making a moisture resistant solar cell is provided. The method includes reducing the roughness of the finger patterns by coating them fully or partially with a surface preparation film. The surface preparation film firmly attaches itself to the underlying busbar and/or busbar and flinger patterns and electrical leads while forming a smooth surface on which a moisture barrier film is subsequently deposited.

In further embodiments are described photovoltaic modules that include one or multiple solar cells, with each of the solar cells including a surface preparation layer that provides as smooth a surface as an active region surface smoothness of a front illuminated conductive surface formed over a terminal structure.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 is a cross-sectional view of a solar cell employing a Group IBIIIAVIA absorber layer.

FIG. 2A is a cross-sectional view of a circuit obtained by monolithic integration of solar cells.

FIG. 2B is a cross-sectional view of a circuit obtained by non-monolithic integration of solar cells.

FIG. 3 shows a module structure obtained by encapsulating the circuit of FIG. 2B in a protective package.

FIGS. 4A and 4B show solar cells first coated with a transparent moisture barrier layer and then integrated into a circuit according to two different embodiments of the invention.

FIG. 5A and 5B show solar cells first integrated into a circuit and then coated with a transparent moisture barrier layer according to two different embodiments of the invention.

FIG. 6 shows a module structure obtained by encapsulating the circuit of FIG. 5A.

FIG. 7A is schematic plan view of a solar cell with a finger pattern including fingers and busbars.

FIG. 7B is a schematic cross sectional view taken along the line A-A′ in the solar cell shown in FIG. 7A.

FIG. 7C is a schematic cross sectional view taken along the line B-B′ in the solar cell shown in FIG. 7A

FIG. 7D is a schematic cross sectional view taken along the line C-C′ in the solar cell shown in FIG. 7A

FIG. 8A is a schematic partial plan view of the solar cell shown in FIG. 7A, wherein electrical leads have been attached to the busbars and a surface preparation layer of the present invention has been coated on the electrical leads and the finger pattern.

FIG. 8B is a schematic cross sectional view taken along the line D-D′ in the solar cell shown in FIG. 8A.

FIG. 9 is a schematic view of the solar cell shown in FIG. 8B, wherein the top of the solar cell including the surface preparation layer has been coated with a moisture barrier material layer.

FIG. 10A is a schematic partial plan view of the solar cell shown in FIG. 7A, wherein electrical leads have been attached to the busbars and a surface preparation layer of the present invention has been coated on the electrical leads and the busbars.

FIG. 10B is a schematic cross sectional view taken along the line E-E′ in the solar cell shown in FIG. 10A.

FIG. 11 is a schematic view of the solar cell shown in FIG. 10B, wherein the top of the solar cell including the surface preparation layer has been coated with a moisture barrier material layer.

FIG. 12 schematically shows a method of manufacturing a solar cell circuit.

### DETAILED DESCRIPTION OF THE EMBODIMENTS

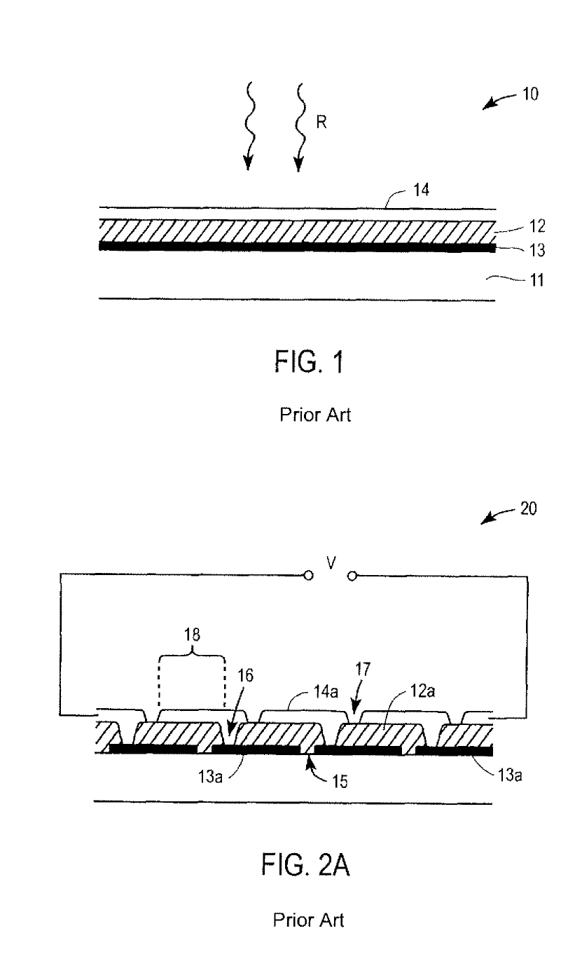

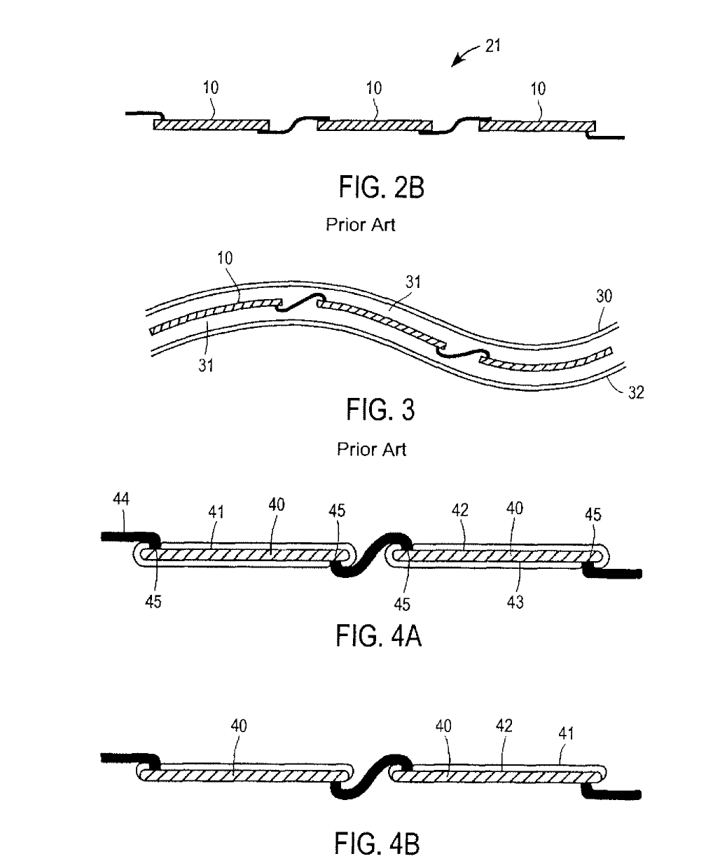

In one embodiment of the present invention. each solar cell in the circuit is individually covered by a transparent moisture barrier material layer before the cells are integrated into circuits and then packaged into modules. FIG. 4A shows two exemplary CIGS(S) solar cells 40 with all the components and layers indicated in FIG. 1. For example, the solar cells 40 may be fabricated on flexible foil substrates, i.e. substrate 11 of FIG. 1, may be a metallic foil. The solar cells 40 are covered by a transparent moisture barrier material layer 41, which as shown in FIG. 4A covers the entire cell 40 including top and bottom surfaces, and in FIG. 4B covers the front illuminated conductive surface 42 of the cell where the light enters the device. The front illuminated conductive surface 42 is the most sensitive surface to protect from moisture and in some cases from oxygen. The transparent moisture barrier material layer 41 or moisture barrier layer or moisture barrier film may optionally wrap around to the back surface 43 of the foil substrate as shown in FIG. 4A. After obtaining the moisture barrier-covered solar cells, integration or interconnection is carried out as shown in FIG. 2B using interconnects such as conductive leads, metallic ribbons or wires 44. For interconnection, the (−) terminal of one cell is electrically connected to the (+) terminal of the other one. This can be achieved through use of soldering wires or ribbons as shown in FIG. 4A. Alternately the cells maybe directly interconnected by overlapping their respective edges and electrically connecting the front electrode of one cell (which is the negative terminal in the case of the device structure shown in FIG. 1) with the back electrode of the next one. It should be noted that if the barrier material layer 41 is highly insulating and thick it should be at least partially removed from the connection points 45 so that good electrical contact may be obtained between the cell electrode and the ribbon or wire.

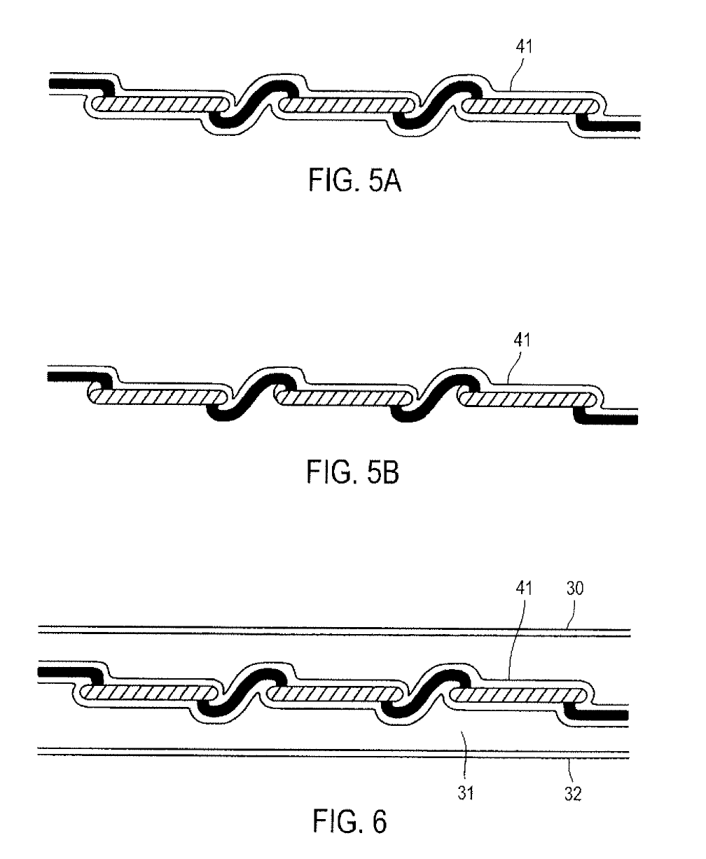

In another approach shown in FIGS. 5(a) and 5(b), the solar cells are first electrically interconnected with a conductor, such as through soldering wires or ribbons, to form a circuit like the one shown in FIG. 2B, and then the whole circuit is covered with a transparent moisture barrier material layer 41, the moisture barrier material 41 either covering the entire circuit, top and bottom, as illustrated in FIG. 5A or as illustrated in FIG. 5B, covering only the side of the circuit that contains the top surface where light enters the device. Some of the advantages of this approach are: i) Since the cells are already interconnected, the step of removing the barrier material layer from the connection points is avoided, ii) since the moisture barrier material layer is deposited after interconnection of the solar cells, the barrier material layer covers all portions of the circuit including the connection points and ribbons or wires. The approach as shown in FIG. 5A provides total encapsulation or coverage by the moisture barrier material layer around the entire circuit, whereas encapsulation and coverage are provided in the FIG. 5B approach on that side where such protection is most needed. Either approach reduces the possibility of moisture or oxygen diffusion through any crack or opening.

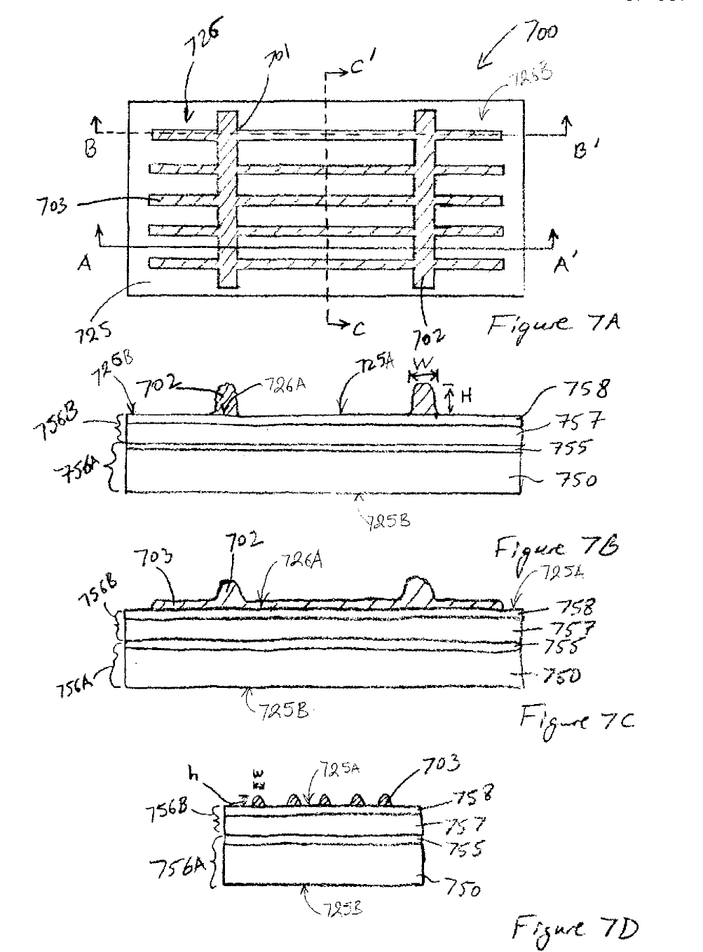

After the circuit is covered by at least one transparent moisture barrier material layer, the structure obtained is a moisture resistant circuit (FIGS. 4A and 4B and FIGS. 5A and 5B). The modules may then be fabricated by various methods such as encapsulating the moisture resistant circuits by a top film 30, an encapsulant 31 and a backing material 32 as shown in FIG. 6. The flexible module obtained by such an approach has a moisture resistant circuit within the module packaging and therefore is environmentally much more stable. It should be noted that use of a backing material 32 is optional in this case. Also the moisture barrier capability of the top film and the backing material is not as important in the module structure of FIG. 6 compared to the structure of FIG. 3, because of the presence of a transparent moisture barrier material layer 41 encapsulating the whole circuit. It should also be noted that the transparent moisture barrier layers may also be used to coat the monolithically integrated structures similar to that shown in FIG. 2A before such monolithically integrated circuits are packaged to form modules.

The transparent moisture barrier material layer may comprise at least one of an inorganic material and a polymeric material. Polyethylene, polypropylene, polystyrene, poly(ethylene terephthalate), polyimide, parylene or poly(chloro-p-xylylene), BCB or benzocyclobutene, polychlorotrifluoroethylene are some of the polymeric materials that can be used as moisture and oxygen barriers. Various transparent epoxies may also be used. Inorganic materials include silicon or aluminum oxides, silicon or aluminum nitrides, silicon or aluminum oxy-nitrides. amorphous or polycrystalline silicon carbide, other transparent ceramics, and carbon doped oxides such as SiOC. These materials are transparent so that when deposited over the transparent conductive contact of the solar cell they do not cause appreciable optical loss. It should be noted that polymeric and inorganic moisture barrier layers may be stacked together in the form of multi-layered stacks to improve barrier performance. Therefore, moisture barrier material layer may be a composite of a stack of films. Layers may be deposited on the solar cells or circuits by a variety of techniques such as by evaporation, sputtering, e-beam evaporation, chemical vapor deposition (CVD), plasma-enhanced CVD (PECVD), organometallic CVD, and wet coating techniques such as dipping, spray coating, doctor blading, spin coating, ink deposition, screen printing, gravure printing, roll coating etc. It is also possible to melt some of the polymeric materials at temperatures below 200 C, preferably below 150 C and coat the melt on the cells and circuits. Thickness of the moisture barrier layers may vary from 50 nm to several hundred microns. One attractive technique is vapor deposition which has the capability of conformal and uniform deposition of materials such as parylene. Parylene has various well known types such as parylene-N, parylene-D and parylene-C. Especially parylene-C is a good moisture barrier that can be vapor deposited on substrates of any shape at around room temperature in a highly conformal manner, filling cracks and even the high aspect ratio (depth-to width ratio) cavities of submicron size effectively. Thickness of parylene layer may be as thin as 50 nm, however for best performance thicknesses higher than 100 nm may be utilized. Another attractive method for depositing moisture barrier layers is spin, spray or dip coating, which, for example may be used to deposit barrier layers of low temperature curable organosiloxane such as P1DX product provided by Silecs corporation. PECVD is another method

FIG. 7A shows a top (illuminated surface) view of an exemplary solar cell 700 such as a thin film CIGS solar cell. The solar cell 700 has a finger pattern 701 or a terminal layer comprising busbars 702 and fingers 703 formed on a contacting region 726A of a front illuminated conductive surface 725A of the solar cell. The contacting region 726A is shown for example in FIGS. 7B and 7C. Light photons enter the solar cell through an exposed surface portion 726B or active region of the front illuminated conductive surface 725A. The exposed surface portion 726B or the active region includes the portion of the front surface 725A that is not covered with the busbars 702 and the fingers 703. Finger patterns are commonly used as top contact or terminal for a solar cell to reduce the overall series resistance of the device. FIGS. 7B, 7C and 7D show the cross sectional sketches of the solar cell 700 taken along the lines A-A′, B-B′ and C-C′, respectively. As can be seen from these figures, the busbars 702 have a width “W” and a thickness “H”, whereas the fingers 703 have a width “w” and a thickness “h”. The typical values of “W” and “H” are in the ranges of 1000-3000 micrometers and 10-30 micrometers, respectively. The typical values of “w” and “h”, on the other hand, are in the ranges of 50-200 micrometers and 5-20 micrometers, respectively. To reduce shadowing losses due to finger coverage of the top surface, to reduce series resistance of the fingers and therefore improve device efficiencies it is desirable to reduce the width of the fingers and the busbars and increase their thicknesses. It should be noted that dimensions of various layers of the solar cell 700 in FIGS. 7A-7D are only representative and they are not drawn to scale. The finger patterns are traditionally fabricated by printing Ag-based inks or pastes using techniques such as screen printing, ink jet printing, ink spraying and ink writing. The inks and pastes typically have Ag particles, sometimes in the form of flakes. As a result, the surfaces of the busbars and fingers are typically much rougher than the top surface 725A of the solar cell 700. For example the average roughness of the top surface may be in the range of 0.05-0.5 micrometers, whereas the average surface roughness of the finger patterns may be 1-100 micrometers.

As shown in FIGS. 7B-7D the solar cell 700 essentially includes a base 756A or a back side having a back surface 725B and a light receiving portion 756B or front side. The base 756A includes a substrate 750 such as a conductive substrate and a contact layer 755 formed on the substrate. The back surface 725B is the back surface of the substrate 750 and also the back surface of the solar cell 700. The light receiving portion 756B may include an absorber layer 757 formed on the contact layer and a transparent layer 758 formed on the absorber layer. Although not explicitly shown in the figures, the transparent layer may include a buffer layer such as a sulfide formed on the absorber layer and a transparent conductive layer such as a transparent conductive oxide formed on the buffer layer. The front conductive illuminated surface 725A of the solar cell 700, on which the fingers 703 and the busbars 702 are formed, is essentially the surface of the transparent layer 758 or the surface of the transparent conductive layer.

Referring to FIGS. 7A-7D, for making the solar cell 700 moisture resistive, at least the exposed surface portion 726B, the finger pattern 701, and optionally the back surface 725B, may be coated with a moisture barrier film. As is already described in the above embodiments, there are a number of methods to apply a moisture barrier film to a solar cell. For example as shown in FIGS. 4A-4B, first the solar cells may be fully coated with a moisture barrier film, and since the electrical leads, such as copper ribbons, need to be attached to the busbars, the insulating moisture barrier film is partially removed to at least partially expose the busbars so that the electrical leads may be attached using conductive adhesive or soldering to them. The same may be done by depositing the moisture barrier film everywhere on the top surface except on top of the busbars. This can be achieved by applying a removable mask to the busbar areas that need to be kept free of the moisture barrier film. The mask may be a removable mask that may be removed from the top of the busbars after the deposition of the moisture barrier film. Busbar areas that are clean of the moisture barrier film may then be easily contacted using copper ribbons. In yet another embodiment, as shown in FIGS. 5A-5B, the electrical leads such as copper ribbons may first be attached to the busbars and then the solar cells including the electrical leads are fully coated with the moisture barrier film.

For moisture barrier films to work, they need to be free from defects such as pinholes. When a moisture barrier film is deposited on a surface, its barrier quality improves as the quality of the surface improves. In other words, defectivity of barrier films is lower on smoother surfaces. As the underlying surface becomes rough, the number of defects or the defect density in the barrier film deposited on the underlying surface increases. In the following embodiments, a surface preparation layer will be used to reduce the roughness of the finger patterns. The surface preparation layer firmly attaches itself to underlying finger patterns and electrical leads while forming a smooth surface on which the moisture barrier film will subsequently be deposited.

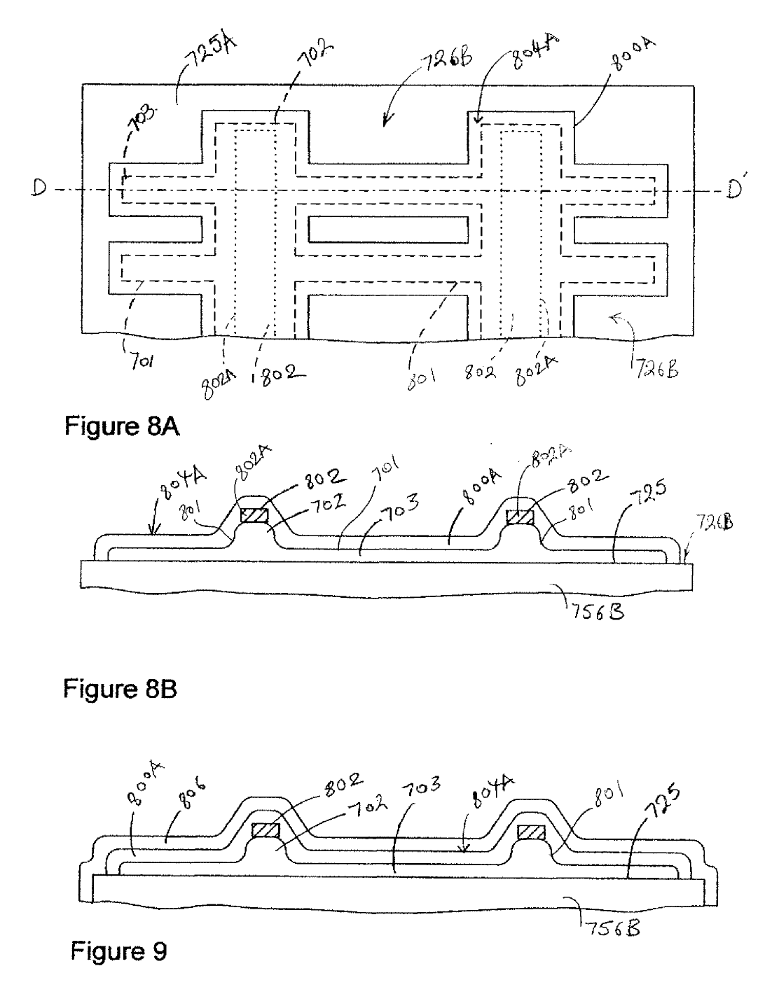

FIGS. 8A, 8B and 9 show another embodiment exemplified using a portion of the solar cell 700 shown in FIG. 7A. As shown in FIG. 8A in top view and in FIG. 8B in cross section, after forming a terminal structure 801 by attaching conductive leads 802 to the finger pattern 701 or conductive terminal layer formed on the contacting region 726A, a surface preparation layer 800A is deposited on the terminal structure 801. The terminal structure 801 may be formed by attaching first ends 802A of the conductive leads 801 to the busbars 702 of the finger pattern 701. A second end (not shown) of the conductive lead may be attached to the conductive substrate of another cell to form a solar cell string or circuit. As shown FIG. 5B, which is a cross sectional view taken along the line DD′ shown in FIG. 8A, the surface preparation layer 800A coats the ends 802A of the electrical leads 802, the exposed surface of busba is and the finger pattern 701, and forms a top surface 804A on them. The surface preparation layer 800A may partially coat the exposed surface portion 726B or the active region of the solar cell 700 along the edges of the finger pattern 701 and seals the edges. The top surface 804A of the surface preparation layer 800A is a smooth surface having less than 50 nm surface roughness in micro scale. In this respect the surface preparation layer 800A planarizes the rough surfaces of the busbars 702, fingers 703 and electrical leads 802, in micro scale, and forms a smooth continuous surface over their exposed surfaces. The surface preparation layer 800A may comprise an opaque material but is preferably transparent, and may or may not be made of a moisture barrier material. It is selected from a material that firmly adheres to the electrical leads, solar cell surface, and the finger patterns. The surface preparation layer is preferably an insulating material and it may be a UV curable material. The thickness of the surface preparation layer 800A may be in the range of 5-100 micrometers preferably 10-50 micrometers, depending on the height and surface roughness of the fingers 703 and/or busbars 702. Although the electrical leads 802 in FIG. 8A are narrower than the busbars 702, they may also be the same width or wider than the busbars. The surface preparation layer may be applied using techniques such as screen printing, inkjet writing etc. For example, the surface preparation layer may be a UV curable material that is first deposited by screen printing and then cured by exposure to UV light. The surface preparation layer may be made of organic resists such as those formulated as inks, thermoplastics, paints etc.

As shown in FIG. 9, after coating the surface preparation layer 800A on the terminal structure 801, the entire top surface of the solar cell 700, including the surface preparation layer 800A and the exposed surface portion 726B of the front illuminated conductive surface 725A is coated with a moisture barrier layer 806. The moisture barrier layer 806 is applied to the light receiving side 756B of the solar cell 700, which coats and adheres to the top surface 804A of surface preparation layer 800A and the front side 756B of the solar cell including the exposed surface portion 726B. The interface between the moisture barrier layer 806 and the surface preparation layer 800A is smooth and defect free, thereby establishing an affective barrier against moisture. If the moisture barrier layer 806 was directly deposited on the surface of the busbars and electrical leads it would have high density of defects due to the rough nature of these device components. Alternatively, the surface preparation layer 800A may be deposited on the terminal structure 801 and the exposed surface portion 726B so that the top of the solar cell 700 is fully covered with the surface preparation layer 800A. In this case the surface preparation layer must be made of a transparent material. When the surface preparation layer is fully coated on the top, the surface of the surface preparation layer may be made planar. In the following step a moisture barrier layer is deposited on this surface preparation layer as shown in FIG. 4B. Further, as shown in FIG. 4A, after depositing the surface preparation layer on top of the solar cells, each solar cell is filly enveloped with the moisture barrier layer by forming the moisture barrier layer on the surface preparation layer and on other exposed surfaces of each solar cell. It is also possible to fully envelop each solar cell with both a surface preparation layer and then a moisture barrier layer on top of it.

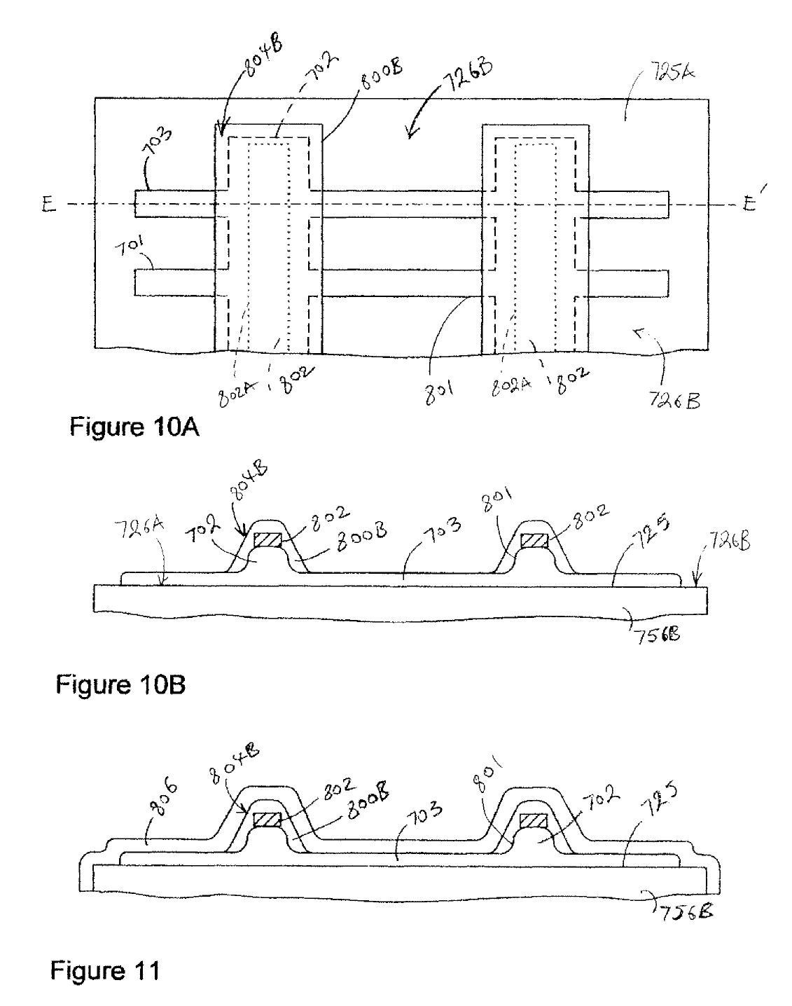

FIGS. 10A, 10B and 11 show another embodiment exemplified using a portion of the solar cell 700 shown in FIG. 7A. As shown in FIG. 10A in top view and in FIG. 10B in cross section, after forming the terminal structure 801 by attaching conductive leads 802 or interconnects to the finger pattern 701 or terminal layer formed on the contacting region 726A, a surface preparation layer 800B is deposited on the first ends 802A of the electrical leads 802 and the exposed surfaces of the busbars 703, but not on the fingers 702. The material of the surface preparation layer 800B is the same as the material of the surface preparation layer 800A. As shown in FIG. 10B, which is a cross sectional view taken along the line EE′ shown in FIG. 10A, the surface preparation layer 800B coats the surfaces of the electrical leads 802 and the busbars. and forms a surface 804B on them. After coating the surface preparation layer 800B, entire solar cell is coated with a moisture barrier layer 806 as shown in FIG. 11. FIG. 11 shows that the moisture barrier layer 806 is applied to the light receiving side of the solar cell, and it coats and adheres to the surface 804B of surface preparation layer 800B and the front side 756B of the solar cell including the exposed surface portion 726. The interface between the moisture barrier layer 806 and the surface preparation layer 800B is smooth and defect free, thereby establishing an affective barrier against moisture. After a string of interconnected solar cells coated with surface preparation layer and moisture barrier layers as described in connection with FIGS. 8A-11 and as described in other embodiments using the surface preparation layer of the present invention, the solar cells are covered with packaging layers 30, 32 or encapsulation layers as shown in FIG. 6. There may or may not be additional moisture barrier layers on the packaging layers 30, 32.

As described in detail above, moisture resistive solar cells of FIGS. 4A, 4B, 9, and 11, as well as the moisture resistive solar cell strings of FIGS. 5A and 5B are obtained by coating these structures, at least partially, by a moisture barrier layer using a variety techniques including, but not limited to evaporation, sputtering, e-beam evaporation, chemical vapor deposition (CVD)), plasma-enhanced CVD (PECVD), organo-metallic CVD, and wet coating techniques such as dipping, spray coating, doctor-blading, spin coating, ink deposition, screen printing. gravure printing, roll coating etc. An example demonstrating how the present inventions may be applied to the fabrication of a moisture resistive module will be described below using the processing steps of making a PV module employing a circuit.

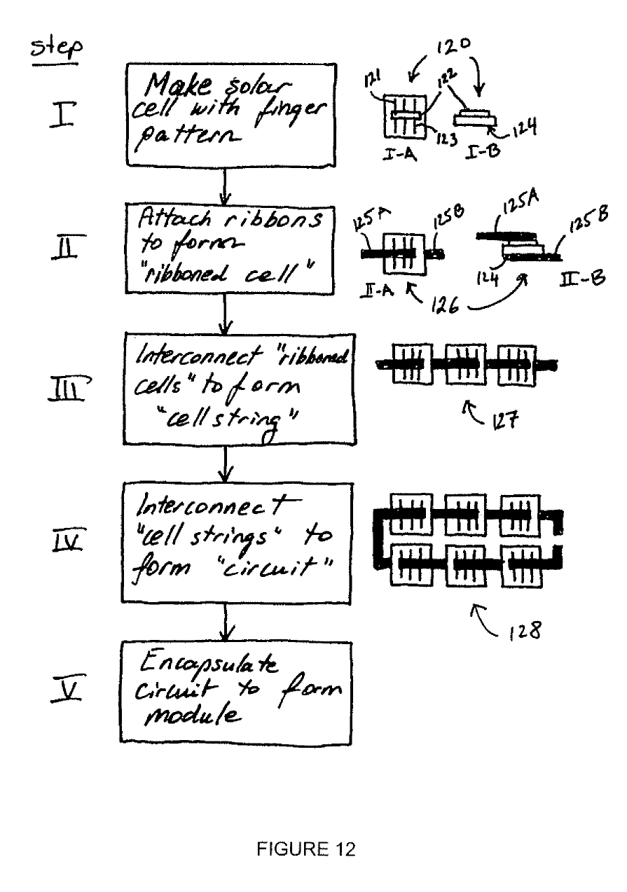

FIG. 12 shows an exemplary process flow for fabricating a PV module. The Step 1 of the flow is the fabrication of a solar cell 120 with a finger pattern 121, the finger pattern 121 comprising at least one busbar 122 and several fingers 123 as can be seen from the top (illuminated face) view I-A and the cross sectional view I-B. The solar cell 120 has a back surface 124, which is the non-illuminated side of the device. The second step of the process (Step 11) involves attaching conductive ribbons 125A and 125B to the busbar 121 and the back surface 124 of the solar cell 120. This way a “ribboned-cell” 126 is obtained as shown in the top view II-A, and the cross-sectional view II-B. The Step III of the process flow is the interconnection of the “ribboned-cells” 126 to form a “cell string” such as the 3-cell “cell string” 127 shown in the figure. In Step IV, the “cell strings” are interconnected to form a “circuit”. The example in FIG. 12 shows two of the 3-cell “cell strings” 127 interconnected to form a 6-cell “circuit” 128. The last step (Step V) is the encapsulation of the “circuit” 128 to form the module.

It should be noted that the moisture barrier layer coating step of the present invention may be applied; between Steps I and II, and/or, between Steps II and III, and/or between steps III and IV, and/or, between Steps IV and V. In other words, as described before, the solar cells fabricated in Step I may be fully or partially encapsulated or coated with a moisture barrier layer and then ribbons may be attached to them forming “ribboned-cells” that are moisture resistant. In this case the areas of the busbar 122 and the back surface 124, where the ribbon attachment would be made, need to be free of the moisture barrier layer to assure low resistance ohmic contact. Ribboned solar cells may then be interconnected to form a string such as the one shown in FIGS. 4A and 4B.

If the moisture barrier layer is applied between Steps II and III, the ribboned-cells 126 are coated by the moisture barrier layer either fully (front or top side as well as the back surface) or partially (front or top side only). These moisture resistant ribboned-cells may then be interconnected in Step III to form a moisture resistant cell string. It should be noted that, in this case, the moisture barrier layer need to be removed or should not be present at locations where the ribbons electrically connect to the adjacent cells so that low contact resistance can be obtained. It should also be noted that the ribboned-cells may also comprise a surface preparation layer that planarizes the rough surfaces of the busbars, fingers and electrical leads or ribbons as shown in FIGS. 8A and 8B. In this case, the structure of FIG. 9 is obtained after the moisture barrier layer is coated over the ribboned-cell.

If the moisture barrier layer is applied between Steps III and IV, the cell strings are coated with the moisture barrier layer either fully or partially, to obtain moisture resistant cell strings such as the ones shown in FIGS. 5A and 5B. These moisture resistant cell strings may then be interconnected in Step IV to form a moisture resistant circuit. It should be noted that, in this case, the moisture barrier layer need to be removed or should not be present at locations where the moisture resistant cell strings electrically connect to each other so that low contact resistance can be obtained.

If the moisture barrier layer is applied between Steps IV and V, the fully formed circuit is coated with the moisture barrier layer either fully or partially, to obtain a moisture resistant circuit. It is also possible to carry out the moisture barrier layer deposition more than once between steps I and V to improve the moisture resistance of the moisture resistive circuit, so that upon encapsulation a module that is highly stable in moist and hot environments may be fabricated.

As the above discussion suggests, the moisture barrier layer may be applied to cells, ribboned cells, cell strings or circuits. For cost lowering purposes it is attractive to apply the barrier layer in a continuous high rate process, or if a batch process is used, to apply it to a large number of cells, ribboned cells, cell strings or circuits. For example, atomic layer deposition (ALD), which is a CVD process, is usually carried out in batch mode because it involves many pump/purge cycles when various chemical species are introduced to the deposition chamber and then removed. Therefore, ALD may be used to practice the present invention as follows. First, a large number of solar cells, ribboned-cells, cell strings or circuits may be formed as described in FIG. 12. A large number of these devices (such as 50, 100, even 1000 or more) may then be introduced in an ALD chamber and a moisture barrier layer may be coated on all the devices at the same time. AID technique is attractive to use because it yields pinhole-free conformal coatings. This way the moisture barrier layer may be coated in a conformal manner over the rough fingers and even in spaces between ribbons and the cells. All defects may also be covered by the moisture barrier layer. Such total and conformal encapsulation with a moisture barrier layer renders the devices (cells, ribboned cells, cell strings or circuits) highly resistive to moisture because there are no pinholes or other defects for the moisture to go through to enter the device structure.

Although the present invention is described with respect to certain preferred embodiments, modifications thereto will be apparent to those skilled in the art.

I claim:

1. A method of manufacturing a moisture resistive photovoltaic module, comprising:
providing two or more solar cells, each of the two or more solar cells having a back conductive surface and a front illuminated conductive surface that includes an active region and a contacting region, wherein a terminal layer that is conductive is disposed over the contacting region;
forming a solar cell circuit by electrically interconnecting the two or more solar cells using interconnects, wherein a first end of each interconnect is attached to a portion of the terminal layer of each of the two or more solar cells to form a terminal structure for each of the two or more solar cells;
forming a surface preparation layer providing as smooth a surface as an active region surface smoothness of the front illuminated conductive surface over the terminal structure of each of the two or more solar cells without substantially extending the surface preparation layer over the active region, the surface preparation layer covering at least the first end of the conductor of each of the two or more solar cells; and
forming a moisture barrier layer over the active region and the surface preparation layer of each of the two or more solar cells.

2. The method of claim 1 wherein the terminal layer comprises at least one busbar and fingers and the first end of the conductor is attached to the at least one busbar.

3. The method of claim 2, wherein the surface preparation layer is disposed over the fingers and the busbar.

4. The method of claim 2, wherein each of the fingers are thinner in width than the at least one busbar, and wherein the surface preparation layer is disposed over only the busbar.

5. The method of claim 1, further comprising encapsulating the solar cell circuit in a protective package.

6. The method of claim 1, wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide

7. The method of claim 1, wherein the step of forming the moisture barrier layer comprises a chemical vapor deposition process.

8. The method of claim 7, wherein the chemical vapor deposition process is an atomic layer deposition process.

9. The method of claim 1, wherein the surface preparation layer comprises one of a paint material an organic resist material and a thermoplastic material.

10. The method of claim 1, wherein the thickness of the surface preparation layer is in the range of 5-100 micrometers.

11. The method of claim 1, wherein the interconnects are copper ribbons.

12. A method of manufacturing a moisture resistive solar cell, comprising:
providing a solar cell having a back surface and a front illuminated conductive surface that includes an active region and a contacting region, wherein a conductive terminal layer is disposed over the contacting region;
attaching a first end of a conductor to a portion of the conductive terminal layer of the solar cell to form a terminal structure;
forming a surface preparation layer providing as smooth a surface as an active region surface smoothness of the front illuminated conductive surface over the terminal structure without substantially extending the surface preparation layer over the active region, the surface preparation layer covering at least the first end of the conductor; and
forming a moisture barrier layer over the active region and the surface preparation layer.

13. The method of claim 12, wherein the conductive terminal layer comprises at least one busbar and fingers and the first end of the conductor is attached to the at least one busbar.

14. The method of claim 13, wherein the surface preparation layer is disposed over the fingers and the at least one busbar.

15. The method of claim 13, wherein each of the fingers are thinner in width than the at least one busbar, and wherein the surface preparation layer is disposed over only the busbar.

16. The method of claim 12, wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride. aluminum nitride, silicon oxy-nitride, aluminum oxy-nitride, amorphous or polycrystalline silicon carbide, transparent ceramics, and carbon doped oxide

17. The method of claim 12, wherein the step of forming the moisture barrier layer comprises a chemical vapor deposition process.

18. The method of claim 17, wherein the chemical vapor deposition process is an atomic layer deposition process.

19. The method of claim 12, wherein the surface preparation layer comprises one of a paint material, an organic resist material and a thermoplastic material.

20. The method of claim 12, wherein the thickness of the surface preparation layer is in the range of 5-100 micrometers.

21. A moisture resistive solar cell, comprising:
a solar cell having a back surface and a front illuminated conductive surface that includes an active region and a contacting region over which a conductive terminal layer is disposed, wherein a first end of a conductor is attached to a portion of the terminal layer of the solar cell to form a terminal structure;
a surface preparation layer that provides as smooth a surface as an active region surface smoothness of the front illuminated conductive surface formed over the terminal structure without substantially extending the surface preparation layer over the active region, the surface preparation layer covering at least the first end of the conductor; and
a moisture barrier layer formed over the active region and the surface preparation layer.

22. The solar cell of claim 21, wherein the surface preparation layer comprises one of a paint material , an organic resist material and a thermoplastic material

23. The solar cell of claim 21, wherein the thickness of the surface preparation layer is in the range of 5-100 micrometers.

24. The solar cell of claim 21, wherein the terminal layer comprises at least one busbar and fingers and the first end of the conductor is attached to the at least one busbar.

25. The solar cell of claim 24, wherein the surface preparation layer is disposed over the lingers and the at least one busbar.

26. The solar cell of claim 24, wherein each of the fingers are thinner in width than the at least one busbar, and wherein the surface preparation layer is disposed over only the busbar.

27. The solar cell of claim 21, wherein the moisture barrier film comprises at least one of polyethylene, polypropylene, polystyrene, poly(ethylene terephthalate), polyimide, parylene, benzocyclobutene, polychlorotrifluoroethylene, silicon oxide, aluminum oxide, silicon nitride, aluminum nitride, silicon oxy-nitride, aluminum oxy-nitride, amorphous or polycrystalline silicon carbide, transparent ceramics, and carbon doped oxide

28. The solar cell of claim 21, wherein the conductor is a copper ribbon.

29. A moisture resistive photovoltaic module, comprising:
a solar cell circuit formed by electrically interconnecting two or more solar cells using interconnects, each of the two or more solar cells having a back conductive surface and a front illuminated conductive surface that includes an active region and a contacting region over which a conductive terminal layer is disposed, wherein a first end of each interconnect is attached to a portion of the terminal layer of each of the two or more solar cells to form a terminal structure for each of the two or more solar cells;
a surface preparation layer that provides as smooth a surface as an active region surface smoothness of the front illuminated conductive surface formed over the terminal structure without extending over the active region, the surface preparation layer covering at least the first end of the conductor; and
a moisture barrier layer formed over the front illuminated surface of each solar cell and the surface preparation layer.

30. The photovoltaic module of claim 29, wherein the surface preparation layer comprises one of a paint material , an organic resist material and a thermoplastic material

31. The photovoltaic module of claim 29, wherein the thickness of the surface preparation layer is in the range of 5-100 micrometers.

32. The photovoltaic module of claim 29, further comprising a protective package in which the solar cell circuit is sealably embedded.

33. The photovoltaic module of claim 29, wherein the terminal layer comprises at least one busbar and fingers and the first end of the conductor is attached to the at least one busbar.

34. The method of claim 33, wherein the surface preparation layer is disposed over the fingers and the at least one busbar.

35. The solar cell of claim 33, wherein each of the fingers are thinner in width than the at least one busbar, and wherein the surface preparation layer is disposed over only the busbar.

36. The method of claim 29, wherein the moisture barrier film comprises at least one of polyethylene. polypropylene, polystyrene, poly(ethylene terephthalate), polyimide, parylene, benzocyclobutene, polychlorotrifluoroethylene, silicon oxide, aluminum oxide, silicon nitride aluminum nitride, silicon oxy-nitride, aluminum oxy-nitride, amorphous or polycrystalline silicon carbide, transparent ceramics, and carbon doped oxide

37. The method of claim 29, wherein the interconnect is a copper ribbon.
